(19) United States
(12) Patent Application Publication
(10) Pub. No.: US 2026/0075854 A1
(43) Pub. Date: Mar. 12, 2026

(54) Power Semiconductor Device, Method of Producing a Power Semiconductor Device, Single-Chip Half-Bridge Inverter, and Method of Operating a Power Semiconductor Device

(71) Applicant: Infineon Technologies Austria AG, Villach (AT)

(72) Inventors: Felix Simon Winterer, München (DE); Lars Müller-Meskamp, Dresden (DE); Anton Mauder, Kolbermoor (DE); Franz Hirler, Isen (DE); Fabian Geisenhof, München (DE); Tom Peterhänsel, Dresden (DE)

(21) Appl. No.: 19/317,830

(22) Filed: Sep. 3, 2025

(30) Foreign Application Priority Data
Sep. 12, 2024 (DE) 102024208687.8

(51) Int. Cl. H10D 12/00; H10D 62/10; H10D 84/00

(52) U.S. Cl. CPC H10D 12/416; H10D 62/109; H10D 84/161

(57) ABSTRACT

A power semiconductor device includes a semiconductor body having a substrate region. The semiconductor body is configured to conduct both a forward load current along a forward direction between first and second load terminals at a front side of the semiconductor body, and a reverse load current along a reverse direction between the first and second load terminals. A first control terminal at the front side is adjacent to the first load terminal. The semiconductor body is configured to establish a first conductive channel based on a first control voltage applied between the first load terminal and the first control terminal. A second control terminal at the front side is adjacent to the second load terminal. The semiconductor body is configured to establish a second conductive channel based on a second control voltage applied between the second load terminal and the second control terminal.

### TECHNICAL FIELD

This specification refers to embodiments of a power semiconductor device and to embodiments of a method of producing a power semiconductor device. The power semiconductor device has a lateral configuration and is configured to conduct both a forward load current and a reverse load current. This specification further refers to embodiments of a single-chip half-bridge inverter and to embodiments of a method of operating a power semiconductor device.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device comprises a semiconductor body configured to conduct a forward load current along a load current path between two load terminals of the device. The load current is conducted by means of an active region of the power semiconductor device. The active region is surrounded by an edge termination region, which is terminated by an edge of the chip.

In case of a controllable power semiconductor device, e.g., a transistor, the load current path may be controlled by means of insulated electrodes, commonly referred to as gate electrodes. For example, upon receiving a corresponding control signal, e.g., from a driver unit and via a control terminal of the device, the control electrodes may set the power semiconductor device in one of a forward conducting state and a forward blocking state.

Furthermore, some devices provide for reverse load current capability; i.e., the active region of the semiconductor body is further configured to conduct a reverse load current along a reverse load current path between the two load terminals of the device. For example, the RC (Reverse Current) IGBT is one representative of such devices. In an RC IGBT, a single chip unites an IGBT structure and a diode structure.

### SUMMARY

The subject-matter of the independent claims is presented. Features of exemplary embodiments are defined in the dependent claims.

According to an embodiment, a power semiconductor device comprises: a semiconductor body including a substrate region of a first conductivity type or of a second conductivity type, wherein the semiconductor body has a front side; at the front side, a first load terminal and a second load terminal, wherein the semiconductor body is configured to conduct both a forward load current along a forward direction between the first load terminal and the second load terminal and a reverse load current along a reverse direction between the first load terminal and the second load terminal. The forward direction and the reverse direction are opposite to each other. The power semiconductor device further comprises at the front side and adjacent to the first load terminal, a first control terminal, wherein the semiconductor body is configured to establish a first conductive channel based on a first control voltage applied between the first load terminal and the first control terminal; and at the front side and adjacent to the second load terminal, a second control terminal, wherein the semiconductor body is configured to establish a second conductive channel based on a second control voltage applied between the second load terminal and the second control terminal.

According to another embodiment, a method of producing a power semiconductor device comprises forming the following components: a semiconductor body including a substrate region of a first conductivity type or of a second conductivity type, wherein the semiconductor body has a front side; at the front side, a first load terminal and a second load terminal, wherein the semiconductor body is configured to conduct both a forward load current along a forward direction between the first load terminal and the second load terminal and a reverse load current along a reverse direction between the first load terminal and the second load terminal. The forward direction and the reverse direction are opposite to each other. The method further comprises, forming, at the front side and adjacent to the first load terminal, a first control terminal, wherein the semiconductor body is configured to establish a first conductive channel based on a first control voltage applied between the first load terminal and the first control terminal; and forming, at the front side and adjacent to the second load terminal, a second control terminal, wherein the semiconductor body is configured to establish a second conductive channel based on a second control voltage applied between the second load terminal and the second control terminal.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIGS. 1-5 each schematically and exemplarily illustrate a vertical cross-section of a power semiconductor device in accordance with some embodiments;

FIG. 6 schematically and exemplarily illustrates a horizontal projection of a single-chip half-bridge inverter in accordance with one or more embodiments;

FIG. 7 schematically and exemplarily illustrates a circuit diagram of a single-chip half-bridge inverter in accordance with one or more embodiments; and

FIGS. 8-9 both schematically and exemplarily illustrate a method of operating a power semiconductor device in accordance with some embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z”herein.

The first conductivity type is opposite to the second conductivity type. In this specification, n-doped is referred to as “first conductivity type” while p-doped is referred to as “second conductivity type”. Alternatively, opposite doping relations can be employed so that the first conductivity type can be p-doped and the second conductivity type can be n-doped. A dopant dose may be defined as the integral over the dopant concentration of the atoms of the respective conductivity type within a respective doping region in a vertical direction Z. The dopant dose may be the amount of dopant implanted per area.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device that may be used within a power converter or a power supply. Thus, in an embodiment, such power semiconductor device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell, a monolithically integrated transistor cell, e.g., a monolithically integrated IGBT or MOSFET cell and/or derivatives thereof. Such diode/transistor cells may be integrated within a single chip. A plurality of such cells may constitute a cell field that is arranged within an active region of the power semiconductor device.

The term “blocking state” of the power semiconductor device may refer to conditions, when the power semiconductor is in a state configured for blocking a load current flow while an external voltage is applied. More particularly, the power semiconductor device may be configured for blocking a forward load current through the power semiconductor device while a forward voltage bias is applied. In comparison, the power semiconductor device may be configured for conducting the forward load current in a “forward conducting state” of the power semiconductor device while a forward voltage bias is applied. A transition between the forward blocking state and the forward conducting state may be controlled by a control electrode or, more particularly, a potential of the control electrode. Said electrical characteristics may, of course, only apply within a predetermined working range of the external voltage and the current density within the power semiconductor device. The term “forward biased blocking state” therefore may refer to conditions with the power semiconductor device being in the forward blocking state while a forward voltage bias is applied.

The term “power semiconductor device” as used in this specification intends to describe a power semiconductor device on a single chip with high voltage blocking and/or high current-carrying capabilities. In other words, such power semiconductor device is intended for high current, typically in the range of several 100 mA, e.g., up to several or ten Ampere, and/or high voltages, typically above 100 V, more typically 300 V and above, e.g., up to at least 600 V or even more, e.g., up to at least 1.2 kV, or even up to 6 kV or more, depending on the respective application.

For example, the term “power semiconductor device” as used in this specification is not directed to logic semiconductor devices that are used for, e.g., storing data, computing data and/or other types of semiconductor-based data processing.

For example, the power semiconductor device described below may be a single semiconductor chip and can be configured to be employed as a power component in a low-, medium-, and/or high voltage application.

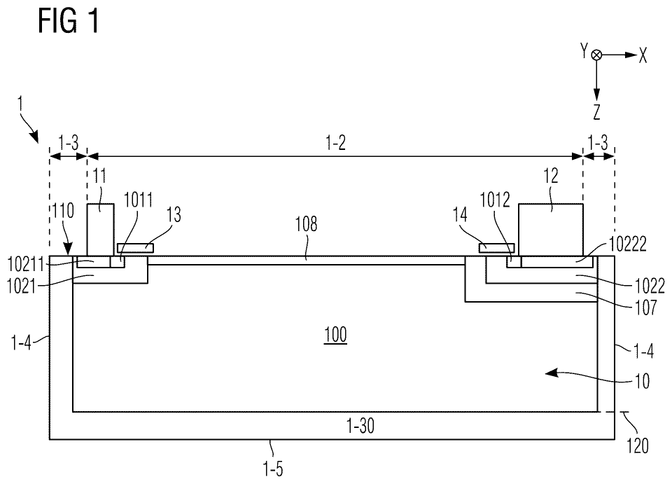

FIG. 1 schematically and exemplarily illustrates a section of a vertical cross-section of a power semiconductor device 1 in accordance with one or more embodiments.

The power semiconductor device 1 comprises a semiconductor body 10 including a substrate region 100 of a first conductivity type or of a second conductivity type, wherein the semiconductor body 10 has a front side 110.

At the front side 110, there is a first load terminal 11 and a second load terminal 12, wherein the semiconductor body 10 is configured to conduct both a forward load current along a forward direction between the first load terminal 11 and the second load terminal 12 and a reverse load current along a reverse direction between the first load terminal 11 and the second load terminal 12. The forward direction and the reverse direction are opposite to each other.

The power semiconductor device 1 further comprises, at the front side 110 and adjacent to the first load terminal 11, a first control terminal 13, wherein the semiconductor body 10 is configured to establish a first conductive channel based on a first control voltage applied between the first load terminal 11 and the first control terminal 13.

Further, at the front side 110 and adjacent to the second load terminal 12, there is arranged a second control terminal 14, wherein the semiconductor body 10 is configured to establish a second conductive channel based on a second control voltage applied between the second load terminal 12 and the second control terminal 14.

For example, based on the second control terminal 14, the power semiconductor device 1 may be operated as a lateral bidirectional power semiconductor transistor, e.g., as a lateral bidirectional IGBT. Furthermore, a high unidirectional voltage blocking capability can be established (e.g., with the second load terminal 12 (e.g., a collector terminal) being at the high voltage), wherein, additionally, a configuration with a bidirectional blocking capability can be established in accordance with some embodiments.

Still referring to FIG. 1, in accordance with an embodiment, the power semiconductor device 1 comprises, in the semiconductor body 10 and laterally overlapping with both the first load terminal 11 and the first control terminal 13, a body region 1021 of the second conductivity type, wherein the body region 1021 is electrically connected to the first load terminal 11, and wherein said first conductive channel is established in the body region 1021.

The power semiconductor device 1 may further comprise in the semiconductor body 10, one or more source regions 1011 of the first conductivity type, wherein the one or more source regions 1011 are electrically connected to the first load terminal 11 and isolated from substrate region 100 by the body region 1021.

For example, said first conductive channel is an inversion channel that extends into the body region 1021.

Furthermore, the body region 1021 may comprise a highly doped subregion 10211 that is electrically connected with, e.g., in contact with, the first load terminal 11.

In an embodiment, several source regions 1011 are arranged spatially separated from each other adjacent to the first load terminal 11, wherein each of the several source regions is isolated from substrate region 100 by the body region 1021. Optionally, one or more (e.g., a corresponding number of) highly doped subregions 10211 may be provided within the body region 1021. For example, a plurality of first conductive channels may be established in the body region 1021, said plurality corresponding to the number of provided source regions 1011.

Both the first control terminal 13 and the second control terminal 14 may be isolated from the semiconductor body 10, e.g., based on a correspondingly configured (non-illustrated) insulator material. Furthermore, the first control terminal 13 is electrically insulated from the second control terminal 14. For example, the first control signal can thus be independent of the second control signal. In other words, the first control signal can be different from the second control signal.

Corresponding to the configuration at the first load terminal 11 and the first control terminal 13, in accordance with an embodiment, the power semiconductor device 1 comprises in the semiconductor body 10 and laterally overlapping with both the second load terminal 12 and the second control terminal 14, a collector region 1022 of the second conductivity type, wherein the collector region 1022 is electrically connected to the second load terminal 12, and wherein said second conductive channel is established in the collector region 1022.

As the body region 1021, also the collector region 1022 may comprise a highly doped subregion 10222 that is electrically connected with, e.g., in contact with, the second load terminal 12.

The power semiconductor device 1 may additionally comprise, in the semiconductor body 10, one or more short regions 1012 of the first conductivity type, wherein the one or more short region 1012 are electrically connected to the second load terminal 12 and isolated from substrate region 100 by the collector region 1022.

In an embodiment, several short regions 1012 are arranged spatially separated from each other adjacent to the second load terminal 12, wherein each of the several short regions is isolated from substrate region 100 by the collector region 1022. Optionally, one or more (e.g., a corresponding number of) highly doped subregions 10222 may be provided within the collector region 1022. For example, a plurality of second conductive channels may be established in the collector region 1022, said plurality corresponding to the number of provided short regions 1012.

In an embodiment, the number of provided short regions 1012 corresponds to the number of provided source regions 1011. In another embodiment, the number of provided short regions 1012 differs from the number of provided source regions 1011.

In accordance with a further embodiment and still referring to FIG. 1, the power semiconductor device 1 comprises a field stop region 107 of the first conductivity type, wherein the collector region 1022 is at least partially isolated from the substrate region 100 by the field stop region 107.

In accordance with a further embodiment and still referring to FIG. 1, the power semiconductor device 1 comprises, a reduced surface field, RESURF, region 108 of the first conductivity type or of the second conductivity type, wherein the RESURF region 108 is arranged at the front side 110 and extends between the first load terminal 11 and the second load terminal 12. For example, the RESURF region 108 adjoins the body region 1021 on the one side and, on the other side, adjoins the field stop region 107. For example, the RESURF region 108 extends from the front side along the vertical direction Z so as to vertically overlap with the both the body region 1021 and the collector region 1022. The RESURF region 108 does not extend, e.g., as far along the vertical direction Z as the body region 1021. In another embodiment, the RESURF region 108 extends as far or further along the vertical direction Z as/than the body region 1021, As illustrated in FIG. 1, the power semiconductor device 1 may comprise an active region 1-2 and a termination region 1-3 surrounding the active region 1-2.

The active region 1-2 is configured for load current conduction (both said forward load current and said revers load current) and accordingly may comprise each of the aforementioned components, namely the four terminals 11, 12, 13 and 14 as well as said semiconductor regions 1011, 1021, 10211, 108, 107, 1022, 10222 and 1012.

The termination region 1-3 is not configured for load current conduction, but serves other purposes such as stabilization of the electric fields and/or sealing the active region 1-2 from the environment of the power semiconductor device 1.

The termination region 1-3 is based on oxide, for example, and terminated by an edge 1-4 and a bottom 1-5, e.g., as illustrated in FIG. 1. For example, the edge 1-4 is a chip edge and/or the bottom 1-5 is a chip bottom. In another embodiment, edge 1-4 is a transition to a further chip region that may accommodate further semiconductor structures. For example, a single chip may accommodate two or more implementations of the power semiconductor device 1, e.g., to form an integrated half-bridge inverter, e.g., as described further below.

In accordance with some embodiments, wherein the semiconductor body 10 can have a thickness, along the vertical direction Z, in the range from 10 μm to 140 μm, e.g., 20 μm to 80 μm. Also, the substrate region 100 may have a thickness, along the vertical direction Z, in the range from the range from 10 μm to 140 μm, e.g., 20 μm to 80 μm.

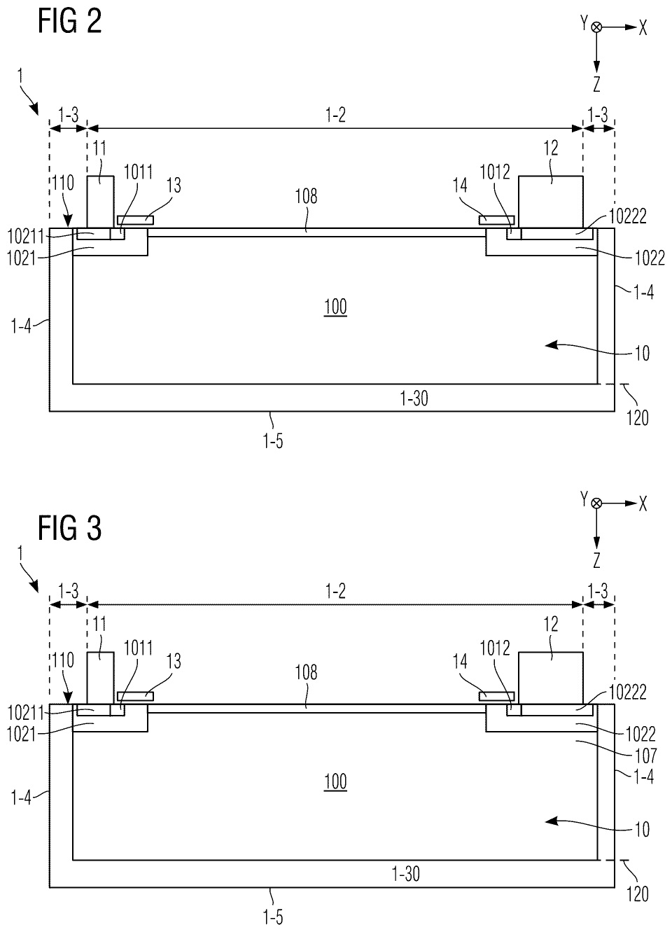

In accordance with the embodiment illustrated in FIG. 1, the substrate region 100 is of the second conductivity type, such that the power semiconductor device 1 may exhibit an n-channel IGBT configuration with a p-doped substrate region 100. In accordance with the embodiment illustrated in FIG. 2, the substrate region 100 is of the first conductivity type, such that the power semiconductor device 1 may exhibit an n-channel IGBT configuration with an n-doped substrate region 100. In accordance with the embodiment illustrated in FIG. 3, the substrate region 100 is of the second conductivity type, i.e., p-doped, wherein the dopant types of each of the body region 1021, the source region 1011, subregion 10211, the RESURF region 108, the collector region 102, subregion 10222 and the short region 1012 are complementary to those of the embodiment illustrated in FIG. 1, such that the power semiconductor device 1 may exhibit a p-channel IGBT configuration with an p-doped substrate region 100.

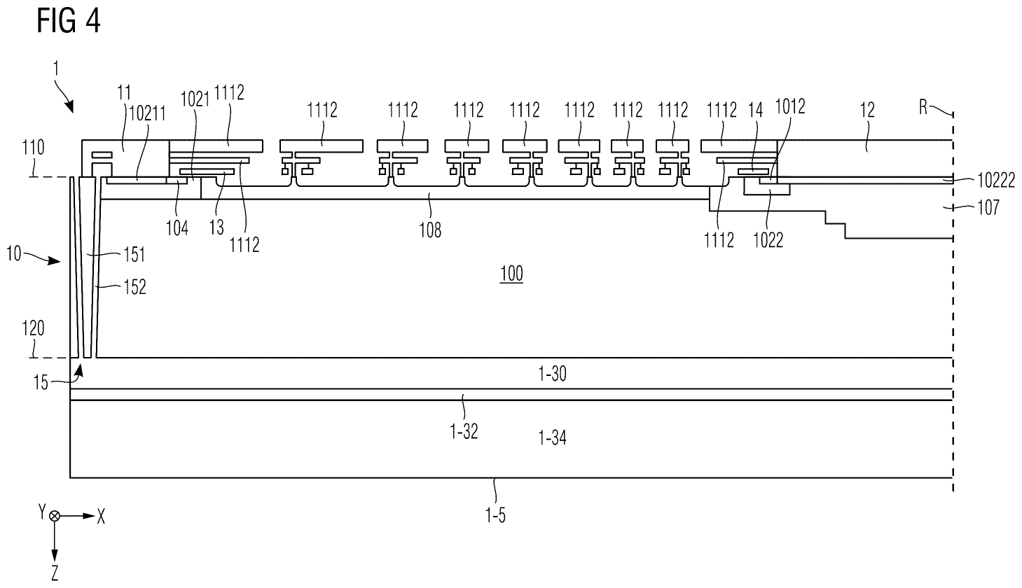

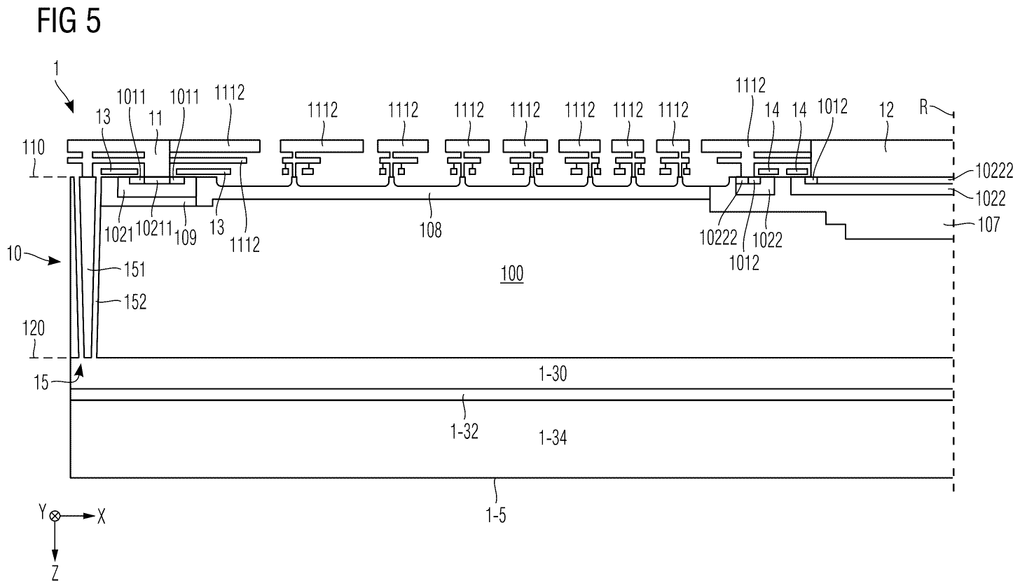

In accordance with the embodiment illustrated in FIG. 4, the power semiconductor device 1 further comprises an insulating trench 15 extending from the front side 110 to the back side 120 of the semiconductor body 10. The insulating trench 15 comprises a trench dielectric 152, which, e.g., also extends from the front side 110 to the back side 120 of the semiconductor body 10 to there adjoin the insulation layer 1-30, and which, e.g., insulates a trench electrode 151 of the insulating trench 15 from the semiconductor body. The trench electrode 151 may be electrically floating or connected with a defined electrical potential, e.g., with the first load terminal 11, as illustrated in FIG. 4. The trench electrode 151 may comprise doped or undoped polycrystalline silicon.

For example, the insulating trench 15 separates the lateral semiconductor structures to the right thereof (which can be configured in accordance with one or more of the embodiments explained above with respect to FIGS. 1 to 3) from other semiconductor structures which may be implemented within the chip. As described above, two or more implementations of the power semiconductor device 1 may be provided within the same single chip, and the insulating trench(es) 15 may be arranged between the two or more implementations of the power semiconductor device 1.

Still referring to FIG. 4, the power semiconductor device 1 may further comprise a field plate structure 1112 arranged above the front side 110 and extending between the first load terminal 11 and the second load terminal 12. The field plate structure 1112 may be electrically connected to the first load terminal 11 on the one side and, on the other side, to the second load terminal 12. The sections of the field plate structure 1112 in between the first load terminal 11 and the second load terminal 12 may be electrically connected with the RESURF region 108, e.g., via a highly doped region (not illustrated). Here, it shall be understood that the illustration in FIG. 4 is only exemplary and that, e.g., the construction and/or the number of the sections of the field plate structure 1112 may be modified. For example, there can be more or fewer sections as illustrated in FIG. 4.

Still referring to FIG. 4, the insulation layer 1-30 may be coupled to a semiconductor (e.g., silicon) substrate region 1-34 via a tape 1-32.

The insulating layer 1-30 may comprise or, respectively, be an oxide layer, as explained above. Said oxide layer may have a thickness along the vertical direction in the range of 0.5 μm to 20 μm, e.g., between 2 μm and 20 μm. The oxide layer may be deposited onto the backside 120. Such approach may allow for a great scalability of the voltage class of the power semiconductor device 1, as the thickness of the deposited oxide can be chosen easily in dependence from the desired breakdown voltage. A combined thickness of the substrate region 100 and the insulating layer 1-30 may be within the range of 20.5 μm to 100 μm, in accordance with an embodiment.

Said semiconductor (e.g., silicon) substrate region 1-34 may be attached directly (without said tape 1-32) or indirectly (e.g., with said tape 1-32) to the insulating layer 1-30. For example, one or more adhesion promotion layers may be arranged in-between the insulating layer 30 and the semiconductor (e.g., silicon) substrate region 1-34. The one or more adhesion promotion layer may include said tape 1-32, e.g., a die-attach-foil, DAF, tape. For example, alternatively or additionally to the one or more adhesion promotion layers, one or more further layers may be arranged in-between the insulating layer 1-30 and the semiconductor (e.g., silicon) substrate region 1-34. The one or more further layers may include one or more dielectric layers and/or one or more metal layers.

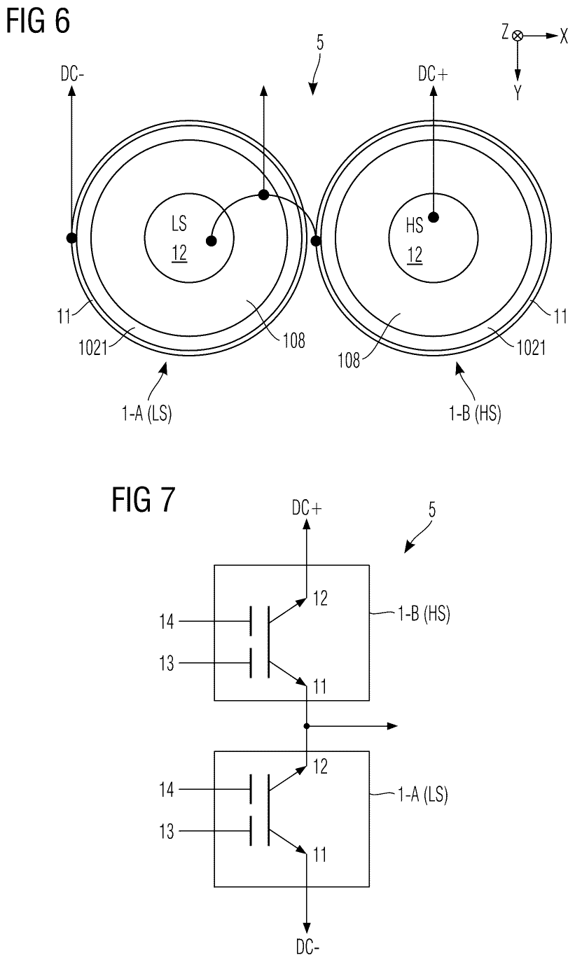

Still referring to FIG. 4, the power semiconductor device 1 may exhibit a configuration that is symmetric with respect to the rotation axis R, yielding a columnar design according to which the second load terminal 12 and associated semiconductor regions are arranged in the center region of the columnar design and according to which the first load terminal 11 and associated semiconductor regions are arranged in the peripheral region of the columnar design (cf. also FIG. 6).

The embodiment illustrated in FIG. 5 corresponds to the embodiment of FIG. 4, wherein, adjacent to the first load terminal 11, two first control terminals 13 and two source regions 1011 are provided. Furthermore, a further field stop region 109 may be provided which separates the body region 102 from the substrate region 100. Likewise, adjacent to the second load terminal 12, two second control terminals 14 and two short regions 1012 are provided. For example, with such design, the channel width can be increase, e.g., doubled, at one or both load terminals, as a channel can also be formed to the outside in the respective body region. This may reduce the voltage drop in the respective channels.

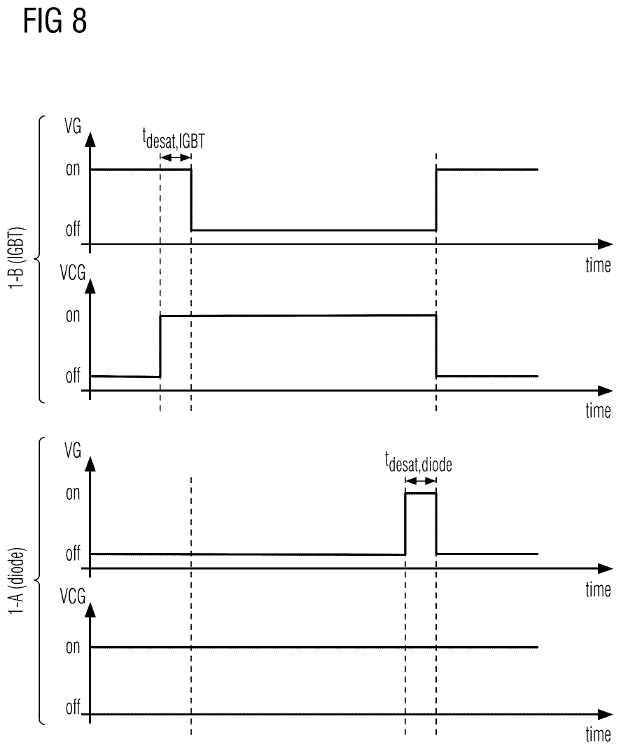

Presented herein are further embodiments of a single-chip half-bridge inverter 5 (cf. FIGS. 7 and 8), wherein the single-chip half-bridge inverter 5 comprises a first power semiconductor device 1-A in accordance with an embodiment described above, and, connected in series thereto, a second power semiconductor device 1-B in accordance with an embodiment described above. The two power semiconductor devices 1-A and 1-B may exhibit the same configuration. The first power semiconductor device 1-A and the second power semiconductor device 1-B are integrated within the same single-chip and, between first power semiconductor device 1-A and the second power semiconductor device 1-B, there may be arranged said insulating trench 15.

FIG. 6 schematically and exemplarily illustrates a horizontal projection of a single-chip half-bridge inverter 5 in accordance with one or more embodiments. For example, the first power semiconductor device 1-A is arranged at a low side, LS, and the second power semiconductor device 1-B is arranged at a high side, HS. FIG. 7 schematically and exemplarily illustrates a proposal for a corresponding circuit diagram of the single-chip half-bridge inverter 5 in accordance with one or more embodiments. The second load terminal 12 of the HS device 1-B is connected to a high side voltage DC+. The first load terminal 11 of the HS device 1-B is connected with the second load terminal 12 of the LS device 1-A. The first load terminal 11 of the LS device 1-A is connected to a low side voltage DC-. Both the first load terminal 11 of the HS device 1-B and the second load terminal 12 of the LS device 1-A are connected with a load L.

In an embodiment, the first power semiconductor device 1-A (e.g., the LS device) is operated both as a first IGBT and as a first free-wheeling diode, and the second power semiconductor device 1-B (e.g., the HS device) is also operated both as a second IGBT and as a second free-wheeling diode.

For example, controlling the first power semiconductor device 1-A (e.g., the LS device) may comprise applying the first control voltage, VG, cf. FIG. 8, between the first load terminal 11 and the first control terminal 13; and applying the second control voltage, VCG, between the second load terminal 12 and the second control terminal 14 of the first power semiconductor device 1-A.

Likewise, controlling the second power semiconductor device 1-B (e.g., the HS device) may comprise applying the first control voltage, VG, cf. FIG. 8, between the first load terminal 11 and the first control terminal 13; and applying the second control voltage, VCG, between the second load terminal 12 and the second control terminal 14 of the second power semiconductor device 1-B.

For example, in FIG. 8, the two upper graphs illustrate the first control signal VG and the second control signal VCG for the second power semiconductor device 1-B (HS device) being in the IGBT mode, and the two lower graphs illustrate the first control signal VG and the second control signal VCG for the first power semiconductor device 1-A (LS device) being in the diode mode. Regarding both devices, a regular IGBT operation is possible in case of the first control signal VG being turned-on (e.g., positive) and the second control signal VCG being turned-off (e.g., zero or negative).

The illustrated control scheme may provide one or more of the following effects:

### Reverse Conducting Operation

When VG is off and VCG is on, the device 1-A is reverse conducting and can be used as a free-wheeling diode. This may save wafer area for the diode.

### Desaturation of the IGBT

By switching VCG on earlier than the IGBT (device 1-B) turns off (cf. duration t_{desat,IGBT} indicated in the upper graph), the plasma density in the IGBT can be reduced before switching. This can be used to substantially reduce IGBT turn-off losses. Furthermore, by switching VCG on earlier than the IGBT turns off may allow for a “glitch-free” operation, wherein small delays in the circuit are not critical.

### Desaturation of the Free-wheeling Diode

By applying a VG pulse to the diode (device 1-A) before the IGBT (device 1-B) turns on (cf. duration t_{desat,diode} diode indicated in the third graph), the diode can be desaturated. This can be used to reduce diode turn-off losses.

The above described control scheme works in the same way for the HS device 1-A being in the diode mode and the LS device 1-B being in the IGBT mode, i.e., when the control schemes 1-A and 1-B in FIG. 8 are swapped.

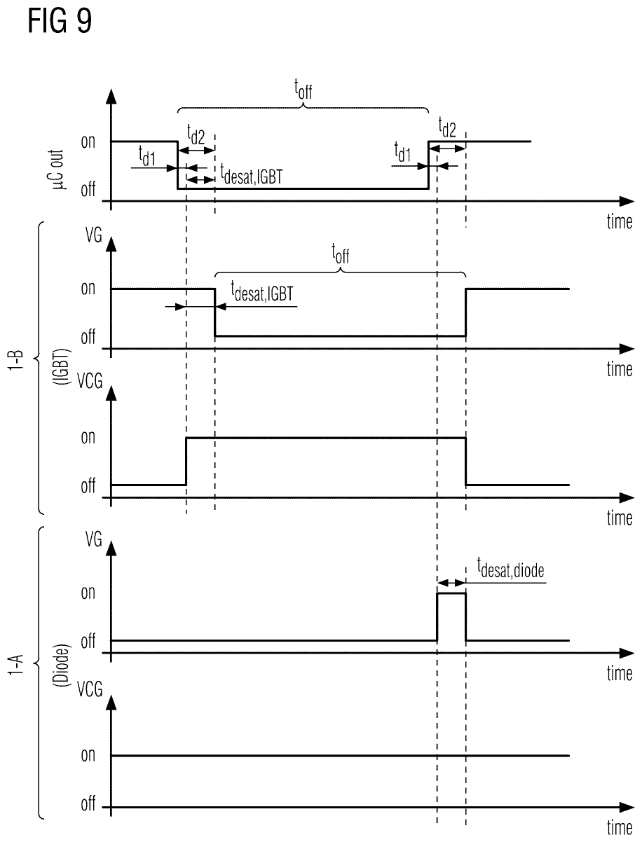

The four lower graphs of FIG. 9 are identical to the four graphs illustrated in FIG. 8. The first/upper graph illustrates an exemplary output of a microcontroller (μC out). As explained with respect to FIG. 8, the pulse for desaturation of the IGBT (cf. cf. duration t_{desat,IGBT} indicated in the two upper graphs) should occur before the actual switching command. However, causality may inhibit direct application of the microcontroller signal to the power semiconductor device. In an embodiment, the first control signal VG and the second control signal VCG are generated based on delayed microcontroller signals with delay times t_{d1} and t_{d2} with respect to an input control signal. Thereby, desaturation pulses can be generated without violating causality and by maintaining the same on and off times as the control algorithm of the microcontroller requests (cf. time period t_{off} shown in second graph).

The above described control schemes apply for devices exhibiting an n-channel configuration. In case of p-channel configurations, the voltages of the first and second control signal VG and VCG would need to be correspondingly adapted, as known to the skilled person.

In an embodiment, a driver providing the first and second control signals VG and VCG is monolithically integrated with the power semiconductor device 1. In case of a failure (e.g., a short circuit), the above described delay will be by-passed and a turn-off command is sent immediately, in accordance with an embodiment.

Presented herein is also a method of producing a power semiconductor device.

For example, the method of producing a power semiconductor device comprises forming the following components: a semiconductor body including a substrate region of a first conductivity type or of a second conductivity type, wherein the semiconductor body has a front side; at the front side, a first load terminal and a second load terminal, wherein the semiconductor body is configured to conduct both a forward load current along a forward direction between the first load terminal and the second load terminal and a reverse load current along a reverse direction between the first load terminal and the second load terminal. The forward direction and the reverse direction are opposite to each other. The method further comprises, forming, at the front side and adjacent to the first load terminal, a first control terminal, wherein the semiconductor body is configured to establish a first conductive channel based on a first control voltage applied between the first load terminal and the first control terminal; and forming, at the front side and adjacent to the second load terminal, a second control terminal, wherein the semiconductor body is configured to establish a second conductive channel based on a second control voltage applied between the second load terminal and the second control terminal.

Embodiments of the above-described method correspond to the embodiments of the power semiconductor device 1 described above. Accordingly, these embodiments of the method will not literally be described herein, but it is referred to the above.

In the above, embodiments pertaining to power semiconductor devices and corresponding production methods were explained.

For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

What is claimed is:

1. A power semiconductor device, comprising:
a semiconductor body including a substrate region of a first conductivity type or of a second conductivity type, wherein the semiconductor body has a front side;
a first load terminal and a second load terminal both at the front side, wherein the semiconductor body is configured to conduct both a forward load current along a forward direction between the first load terminal and the second load terminal, and a reverse load current along a reverse direction between the first load terminal and the second load terminal, wherein the forward direction and the reverse direction are opposite to each other;
a first control terminal at the front side and adjacent to the first load terminal, wherein the semiconductor body is configured to establish a first conductive channel based on a first control voltage applied between the first load terminal and the first control terminal; and
a second control terminal at the front side and adjacent to the second load terminal, wherein the semiconductor body is configured to establish a second conductive channel based on a second control voltage applied between the second load terminal and the second control terminal.

2. The power semiconductor device of claim 1, further comprising:
a body region of the second conductivity type in the semiconductor body and laterally overlapping with both the first load terminal and the first control terminal, wherein the body region is electrically connected to the first load terminal, and wherein the first conductive channel is established in the body region.

3. The power semiconductor device of claim 2, further comprising:
one or more source regions of the first conductivity type in the semiconductor body, electrically connected to the first load terminal and isolated from substrate region by the body region.

4. The power semiconductor device of claim 2, wherein a plurality of first conductive channels is established in the body region based on the number of source regions.

5. The power semiconductor device of claim 1, further comprising:
a collector region of the second conductivity type in the semiconductor body and laterally overlapping with both the second load terminal and the second control terminal, wherein the collector region is electrically connected to the second load terminal, and wherein the second conductive channel is established in the collector region.

6. The power semiconductor device of claim 5, further comprising:
one or more short regions of the first conductivity type in the semiconductor body, electrically connected to the second load terminal and isolated from substrate region by the collector region.

7. The power semiconductor device of claim 6, wherein a plurality of second conductive channels are established in the collector region based on the number of short regions.

8. The power semiconductor device of claim 5, further comprising:
a field stop region of the first conductivity type in the semiconductor body, wherein the collector region is at least partially isolated from the substrate region by the field stop region.

9. The power semiconductor device of claim 1, further comprising:
a reduced surface field (RESURF) region of the first conductivity type or of the second conductivity type in the semiconductor body, wherein the RESURF region is arranged at the front side and extends between the first load terminal and the second load terminal.

10. The power semiconductor device of claim 1, wherein the first control terminal is electrically insulated from the second control terminal.

11. The power semiconductor device of claim 1, wherein the first control signal is independent of the second control signal.

12. The power semiconductor device of claim 1, wherein the semiconductor body and/or the substrate region has a thickness in a range from 10 μm to 140 μm.

13. The power semiconductor device of claim 1, further comprising:
an insulating layer at a back side of the semiconductor body.

14. The power semiconductor device of claim 1, further comprising:
an insulating trench extending from the front side to a back side of the semiconductor body, the insulating trench comprising a trench dielectric.

15. The power semiconductor device of claim 1, wherein the power semiconductor device has a lateral IGBT configuration.

16. A single-chip half-bridge inverter comprising:
a first power semiconductor device according to claim 1; and
a second power semiconductor device according to claim 1 connected in series with the first power semiconductor device.

17. The single-chip half-bridge inverter of claim 16, wherein the first power semiconductor device and the second power semiconductor device are integrated within a same single-chip.

18. The single-chip half-bridge inverter of claim 16, wherein the first power semiconductor device is configured to operate both as a first IGBT and as a first free-wheeling diode, and wherein the second power semiconductor device is configured to operate both as a second IGBT and as a second free-wheeling diode.

19. A method of operating a power semiconductor device that includes a semiconductor body having a substrate region of a first conductivity type or of a second conductivity type, the semiconductor body having a front side and a first load terminal and a second load terminal both at the front side, a first control terminal at the front side and adjacent to the first load terminal, and a second control terminal at the front side and adjacent to the second load terminal, the semiconductor body configured to conduct both a forward load current along a forward direction between the first load terminal and the second load terminal, and a reverse load current along a reverse direction between the first load terminal and the second load terminal, the method comprising:
applying a first control voltage between the first load terminal and the first control terminal, wherein the semiconductor body establishes a first conductive channel based on the first control voltage; and
applying a second control voltage between the second load terminal and the second control terminal, wherein the semiconductor body establishes a second conductive channel based on the second control voltage.

20. A method of producing a power semiconductor device, comprising:
forming a semiconductor body that includes a substrate region of a first conductivity type or of a second conductivity type, wherein the semiconductor body has a front side;
forming both a first load terminal and a second load terminal at the front side, wherein the semiconductor body is configured to conduct both a forward load current along a forward direction between the first load terminal and the second load terminal, and a reverse load current along a reverse direction between the first load terminal and the second load terminal, wherein the forward direction and the reverse direction are opposite to each other;
forming a first control terminal at the front side and adjacent to the first load terminal, wherein the semiconductor body is configured to establish a first conductive channel based on a first control voltage applied between the first load terminal and the first control terminal; and
forming a second control terminal at the front side and adjacent to the second load terminal, wherein the semiconductor body is configured to establish a second conductive channel based on a second control voltage applied between the second load terminal and the second control terminal.
